(19) United States
(12) Patent Application Publication
(10) Pub. No.: US 2021/0034070 A1
(43) Pub. Date: Feb. 4, 2021

(54) ROBOT

(71) Applicant: Seiko Epson Corporation, Tokyo (JP)

(72) Inventor: Mitsuhiro YAMAMURA, Suwa (JP)

(21) Appl. No.: 16/941,833

(22) Filed: Jul. 29, 2020

(30) Foreign Application Priority Data
Jul. 30, 2019 (JP) 2019-139495

(51) Int. Cl. G05D 1/02; G01D 5/24

(52) U.S. Cl. CPC G05D 1/0259; G01D 5/24

(57) ABSTRACT

A robot includes a first arm, a second arm to be displaced relative to the first arm, a capacitance-type first proximity sensor provided on the second arm, and a capacitance-type second proximity sensor provided on the second arm, wherein a distance from the first arm to the first proximity sensor is different from a distance from the first arm to the second proximity sensor.

The present application is based on, and claims priority from JP Application Serial Number 2019-139495, filed Jul. 30, 2019, the disclosure of which is hereby incorporated by reference herein in its entirety.

### BACKGROUND

### 1. Technical Field

The present disclosure relates to a robot.

### 2. Related Art

JP-A-2018-149673 discloses a vertical articulated robot including three arms. Non-contact sensor devices having capacitance proximity switches on outer circumferential surfaces thereof are wrapped around the respective arms of the robot. When a human enters sensor detection ranges by the respective non-contact sensor devices, detection signals are input to a control box via lead wires. The control box is configured to receive the detection signals and control the respective robot arms to urgently stop or decelerate their motion.

Further, the respective non-contact sensor devices include sensitivity adjustment volumes. The sensitivity is set to be lower in the sensitivity adjustment volumes, and thereby, the sensor detection ranges may be set to be narrower. Or, the sensitivity may be set to be higher.

Here, the three arms of the robot disclosed in JP-A-2018-149673 are referred to as “first arm”, “second arm”, and “third arm”. Joint portions each pivotably coupling one arm to the other arm intervene between the first arm and the second arm and between the second arm and the third arm. Accordingly, for example, when the first arm or the third arm pivots to approach the non-contact sensor device provided on the second arm, capacitance is larger between the non-contact sensor device and the first arm or the third arm and, as a result, false detection of approach of an object or human to the sensor detection range may occur. To avoid the false detection, measures to reduce the sensitivity of the non-contact sensor device are considered. However, when the sensitivity is reduced, a problem that detection of approach of an object or human is harder arises.

### SUMMARY

A robot according to an application example of the present disclosure includes a first arm, a second arm to be displaced relative to the first arm, a capacitance-type first proximity sensor provided on the second arm, and a capacitance-type second proximity sensor provided on the second arm, wherein a distance from the first arm to the first proximity sensor is different from a distance from the first arm to the second proximity sensor.

### BRIEF DESCRIPTION OF THE DRAWINGS

FIG. 1 is a perspective view showing a robot according to an embodiment.

FIG. 2 is a system configuration diagram of the robot and a control apparatus shown in FIG. 1.

FIG. 3 is a front view of the robot shown in FIG. 1.

FIG. 4 is a schematic side view of a posture in which a first arm, a second arm, and a third arm of the robot shown in FIG. 1 do not overlap.

FIG. 5 is a partial sectional view of a proximity sensor shown in FIG. 1.

FIG. 6 is a partially enlarged view of a robot arm shown in FIG. 3.

FIG. 7 is a block diagram showing the proximity sensor in FIG. 6 and a first sensor circuit and a second sensor circuit in FIG. 2.

FIG. 8 shows a placement example of a proximity sensor, a placement example of a sensor circuit, and a wiring example in a robot of related art.

FIG. 9 is a front view showing a placement of the proximity sensor in FIG. 6 and a placement of the first sensor circuit and the second sensor circuit in FIG. 2.

FIG. 10 is a partially enlarged view showing proximity sensors placed on a second arm of a robot according to a first modified example.

FIG. 11 is a partially enlarged view showing proximity sensors placed on a second arm of a robot according to a second modified example.

### DESCRIPTION OF EXEMPLARY EMBODIMENTS

As below, a preferred embodiment of a robot according to the present disclosure will be explained in detail with reference to the accompanying drawings.

### 1. Robot

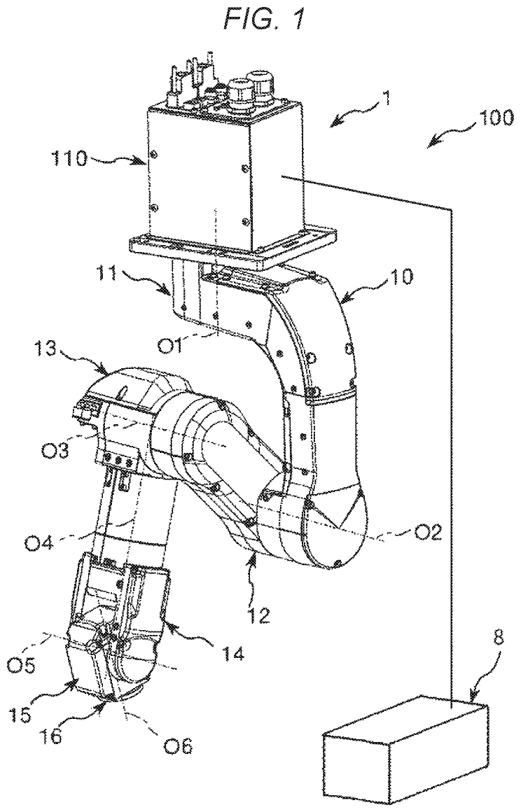

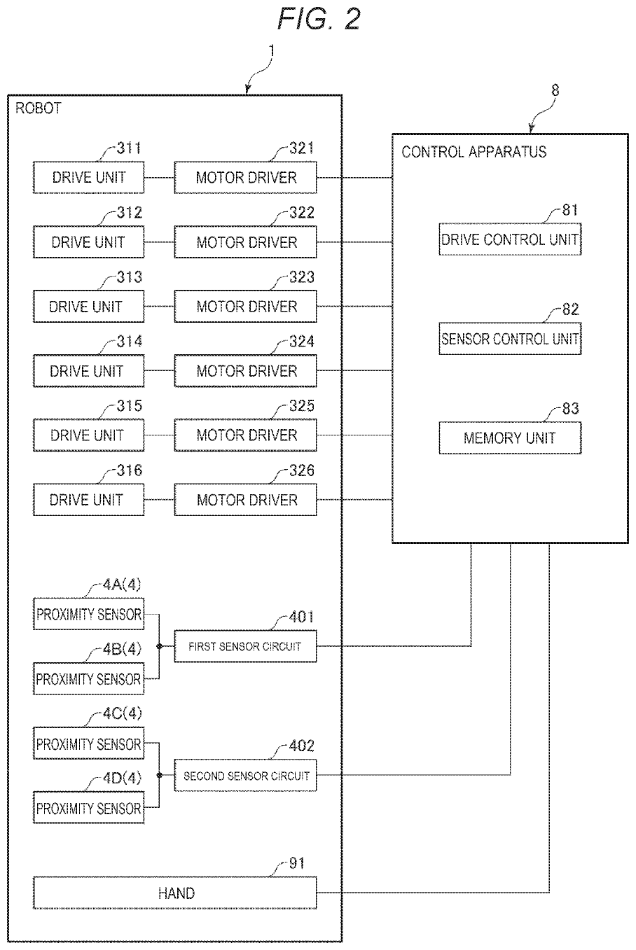

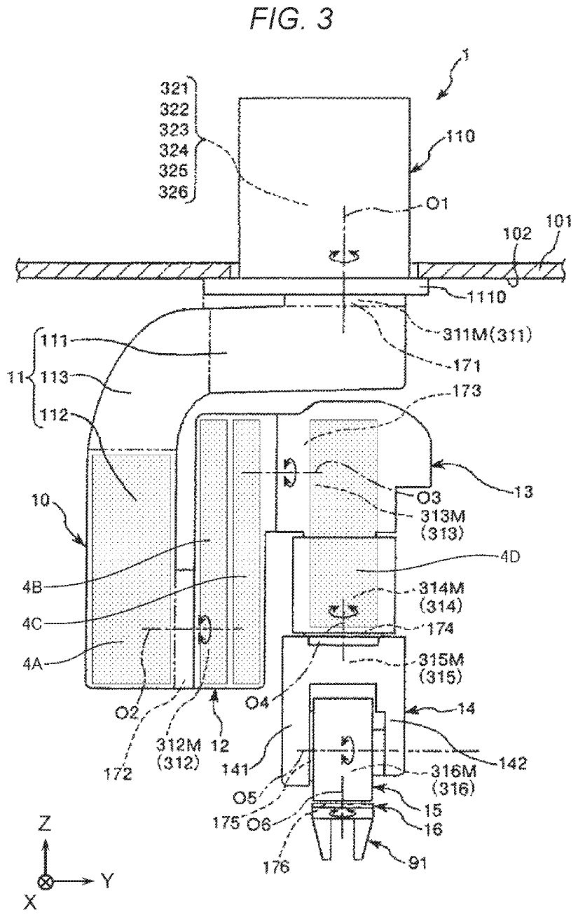

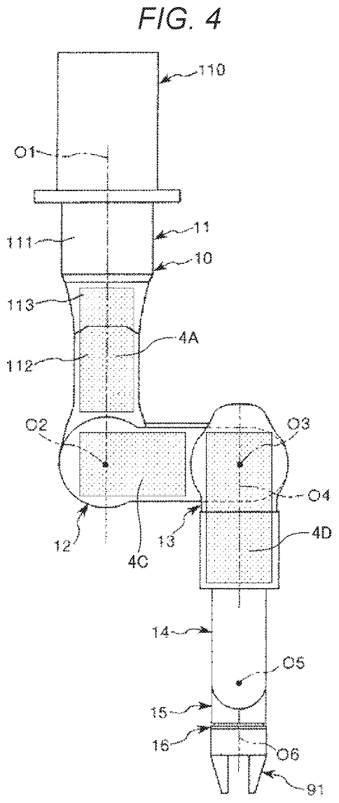

FIG. 1 is the perspective view showing the robot according to the embodiment. FIG. 2 is the system configuration diagram of the robot and the control apparatus shown in FIG. 1. FIG. 3 is the front view of the robot shown in FIG. 1. FIG. 4 is the schematic side view of the posture in which the first arm, the second arm, and the third arm of the robot shown in FIG. 1 do not overlap.

As below, in the respective drawings, vertical axes extend upward and downward and the upsides in the respective drawings are referred to as “vertical upsides” and the downsides in the respective drawings are referred to as “vertical downsides”. Further, particularly in FIG. 3, the vertical axis is referred to as “Z-axis” and shown by an arrow. In FIG. 3, two axes orthogonal to each other within the horizontal plane orthogonal to the vertical axis are referred to as “X-axis” and “Y-axis” and respectively shown by arrows. Note that the head sides of the arrows indicating the respective axes are referred to as “plus sides” and the tail sides are referred to as “minus sides”. In the following explanation, a side of a base 110 of a robot arm 10 is referred to as “proximal end side” and a distal end side of the robot arm 10 is referred to as “distal end side”.

A robot 100 shown in FIG. 1 has a robot main body 1 and a control apparatus 8 that controls actuation of the robot main body 1.

The robot 100 is used for work of gripping, transport, assembly, etc. of objects such as electronic components and electronic apparatuses. In this case, the robot main body 1 performs work of gripping, transport, assembly, etc. of objects under control by the control apparatus 8.

The robot main body 1 shown in FIGS. 1 to 3 has the base 110, the robot arm 10, and a proximity sensor 4. Further, as shown in FIG. 2, the robot main body 1 includes a plurality of drive units 311 to 316 and a plurality of motor drivers 321 to 326 that generate power to drive the robot arm 10 shown in FIG. 1. Furthermore, as shown in FIG. 3, a hand 91 as an end effector is detachably attached to the distal end portion of the robot arm 10.

### 1.1 Base

The base 110 shown in FIG. 1 is a portion attached to a predetermined location and supports the robot arm 10.

The robot main body 1 in the embodiment is the so-called suspended vertical articulated robot. The base 110 is located at the vertical uppermost side of the robot main body 1 and attached to an attachment surface 102 of a ceiling 101 within an installation space of the robot main body 1. In the embodiment, the base 110 is located at the vertical upside of a first arm 11 and workability in a region at the vertical downside may be improved in the robot main body 1.

Note that, in the embodiment, a plate-like flange surface 1110 provided in the lower part of the base 110 is fixed to the attachment surface 102, however, the portion fixed to the attachment surface 102 is not limited to that, but may be e.g. the upper surface of the base 110. The fixing method is not particularly limited, but e.g. a fixing method using a plurality of bolts may be employed. The location to which the base 110 is fixed is not limited to the ceiling 101, but may be e.g. a wall, floor, ground, or the like in the installation space.

### 1.2 Robot Arm

The robot arm 10 shown in FIG. 1 is pivotably supported relative to the base 110.

The robot arm 10 has the first arm 11, a second arm 12, a third arm 13, a fourth arm 14, a fifth arm 15, and a sixth arm 16. The first arm 11 is coupled to the lower end portion of the base 110. The first arm 11, the second arm 12, the third arm 13, the fourth arm 14, the fifth arm 15, and the sixth arm 16 are sequentially coupled from the proximal end side toward the distal end side. These arms 11 to 16 are displaceably supported relative to the base 110 independently from one another. The robot main body 1 is the vertical articulated robot having the six arms 11 to 16, and has a wider driving range and exerts higher workability.

As shown in FIG. 3, the first arm 11 has a curved or bent shape and the proximal end portion thereof is coupled to the base 110. The first arm 11 has a first portion 111 coupled to the base 110 and extending along the horizontal plane, a second portion 112 coupled to the second arm 12 and extending along the vertical axis, and a third portion 113 located between the first portion 111 and the second portion 112 and extending in a direction oblique to the horizontal surface and the vertical axis. Note that the first portion 111, the second portion 112, and the third portion 113 are integrated.

The second arm 12 has an elongated shape and is coupled to the distal end portion of the first arm 11.

The third arm 13 has an elongated shape and is coupled to the opposite end portion of the second arm 12 to the end portion to which the first arm 11 is coupled.

The fourth arm 14 is coupled to the opposite end portion of the third arm 13 to the end portion to which the second arm 12 is coupled. The fourth arm 14 has a pair of supporting portions 141, 142 facing each other. The supporting portions 141, 142 are used for coupling to the fifth arm 15. Note that the fourth arm 14 is not limited to the structure, but may have e.g. a single supporting portion.

The fifth arm 15 is located between the supporting portions 141, 142 and attached to the supporting portions 141, 142 to be coupled to the fourth arm 14.

The sixth arm 16 has a circular plate shape in a plan view and is coupled to the distal end portion of the fifth arm 15. Further, the hand 91 is detachably attached to the distal end portion of the sixth arm 16. Note that, in the embodiment, the hand 91 is taken as an example of the end effector, however, the end effector is not limited to the hand 91. The end effector may be e.g. a suction mechanism that suctions an object, a processing mechanism that performs processing or the like on an object, or the like.

The exterior members of the respective arms 11 to may be respectively single members or formed by pluralities of members.

The base 110 and the first arm 11 are coupled via a joint 171. The joint 171 pivotably supports the first arm 11 relative to the base 110. Thereby, the first arm 11 is pivotable about a first pivot axis O1 along the vertical axis relative to the base 110. The first arm 11 pivots by the drive unit 311 having a motor 311M.

The first arm 11 and the second arm 12 are coupled via a joint 172. The joint 172 pivotably supports the second arm 12 relative to the first arm 11. Thereby, the second arm 12 is pivotable about a second pivot axis O2 along the horizontal plane relative to the first arm 11. The second arm 12 pivots by the drive unit 312 having a motor 312M.

The second arm 12 and the third arm 13 are coupled via a joint 173. The joint 173 pivotably supports the third arm 13 relative to the second arm 12. Thereby, the third arm 13 is pivotable about a third pivot axis O3 along the horizontal plane relative to the second arm 12. The third arm 13 pivots by the drive unit 313 having a motor 313M.

The third arm 13 and the fourth arm 14 are coupled via a joint 174. The joint 174 pivotably supports the fourth arm 14 relative to the third arm 13. Thereby, the fourth arm 14 is pivotable about a fourth pivot axis O4 orthogonal to the third pivot axis O3 relative to the third arm 13. The fourth arm 14 pivots by the drive unit 314 having a motor 314M.

The fourth arm 14 and the fifth arm 15 are coupled via a joint 175. The joint 175 pivotably supports the fifth arm 15 relative to the fourth arm 14. Thereby, the fifth arm 15 is pivotable about a fifth pivot axis O5 orthogonal to the fourth pivot axis O4 relative to the fourth arm 14. The fifth arm 15 pivots by the drive unit 315 having a motor 315M.

The fifth arm 15 and the sixth arm 16 are coupled via a joint 176. The joint 176 pivotably supports the sixth arm 16 relative to the fifth arm 15. Thereby, the sixth arm 16 is pivotable about a sixth pivot axis O6 orthogonal to the fifth pivot axis O5 relative to the fifth arm 15. The sixth arm 16 pivots by the drive unit 316 having a motor 316M.

As described above, the robot main body 1 has the plurality of drive units 311 to 316 in the number corresponding to the respective arms 11 to 16. The drive units 311 to 316 have the above described corresponding motors 311M to 316M and reducers that reduce rotation of the motors 311M to 316M, respectively. The motors 311M to 316M are electrically coupled to the corresponding motor drivers 321 to 326 and controlled by the control apparatus via the corresponding motor drivers 321 to 326, respectively. The motor drivers 321 to 326 shown in FIG. 3 are provided inside of the base 110.

Note that, in the respective drive units 311 to 316, e.g. angle sensors such as encoders or rotary encoders (not shown) are provided. Thereby, the rotation angles of the motors or reducers of the respective drive units 311 to 316 may be detected.

The configuration of the robot arm 10 is not limited to that described above. For example, one arm may linearly move, not pivot relative to the adjacent arm or base. In this specification, pivot and linear motion are collectively referred to as “displacement”.

### 1.3 Control Apparatus

The control apparatus 8 shown in FIG. 2 is formed by e.g. a personal computer including a CPU (Central Processing Unit), RAM (Random Access Memory), and ROM (Read Only Memory) or the like.

The control apparatus 8 has a drive control unit 81, a sensor control unit 82, and a memory unit 83. The drive control unit 81 has a function of respectively independently controlling driving conditions e.g. angular velocities or rotation angles of the plurality of drive units 311 to 316 based on e.g. detection results input from various sensors or the like. The sensor control unit 82 controls actuation of the proximity sensor 4. Specifically, the unit determines whether or not an object approaches the proximity sensor 4 based on a detection result by the proximity sensor 4. Then, the unit outputs the detection result to the drive control unit 81. The memory unit 83 has a function of recording programs, various data, etc. for controlling driving of the drive units 311 to 316.

The control apparatus 8 may sequentially control the work by the respective units of the robot main body 1 according to e.g. a predetermined program. Accordingly, the apparatus may perform high-accuracy motion control of the robot main body 1.

Note that the control apparatus 8 according to the embodiment is separately provided from the robot main body 1, however, a part or all thereof may be provided inside of the robot main body 1. Further, the coupling between the robot main body 1 and the control apparatus 8 may be wired or wireless.

### 1.4 Proximity Sensor

The proximity sensor 4 is placed on the outer surface of the robot arm 10. The proximity sensor 4 is a sensor that detects an approaching object. In FIGS. 3 and 4, the areas with the proximity sensor 4 placed therein are dotted. The proximity sensor 4 according to the embodiment is placed over a wide range on the outer surfaces of the first arm 11, the second arm 12, and the third arm 13. Note that the dotted areas are examples and not limited to the illustrated areas.

Further, the proximity sensor 4 according to the embodiment is divided into four portions of proximity sensors 4A, 4B, 4C, 4D. The proximity sensor 4A is placed on the outer surface of the first arm 11, the proximity sensors 4B, 4C are respectively placed on the outer surface of the second arm 12, and the proximity sensor 4D is placed on the outer surface of the third arm 13.

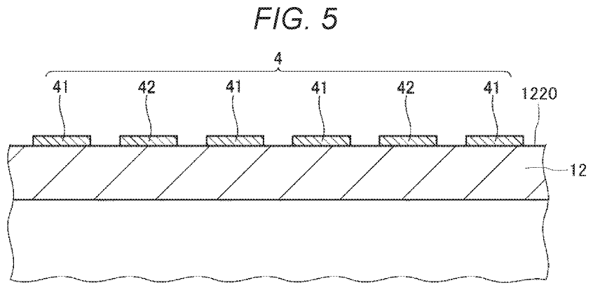

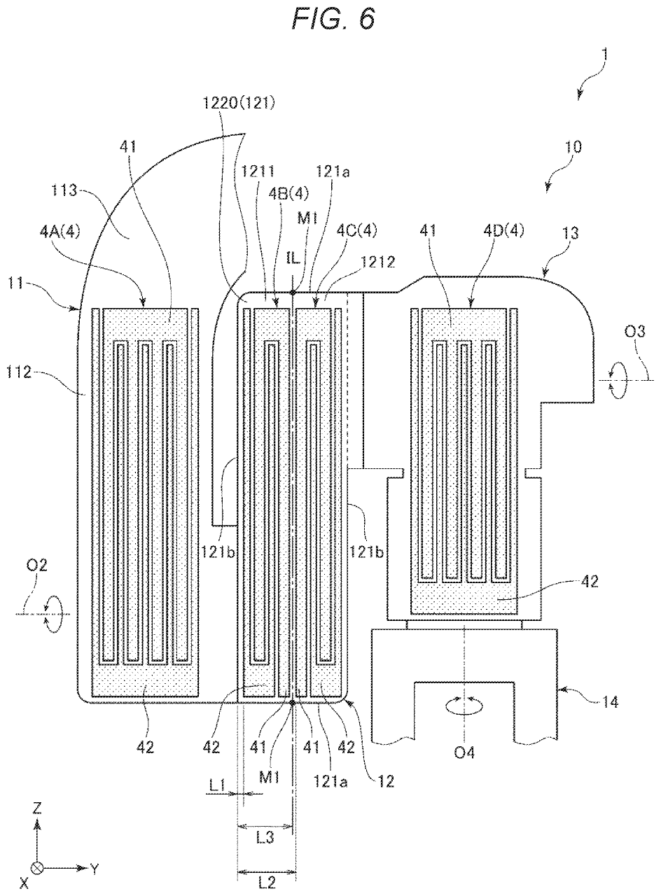

FIG. 5 is the partial sectional view of the proximity sensor 4 shown in FIG. 1. FIG. 6 is the partially enlarged view of the robot arm 10 shown in FIG. 3.

The proximity sensor 4 shown in FIG. 5 is a capacitance sensor that detects whether or not an object approaches based on a change of capacitance. The proximity sensor 4 has a drive electrode 41 and a detection electrode 42. The drive electrode 41 and the detection electrode 42 are provided apart from each other on an outer surface 1220 of the second arm 12. Thereby, the drive electrode 41 and the detection electrode 42 are insulated. Further, the drive electrode 41 and the detection electrode 42 have comb-teeth shapes in a plan view of the outer surface 1220 as shown in FIG. 6. The electrodes are placed with the comb teeth of the drive electrode 41 and the comb teeth of the detection electrode 42 separated from each other side by side with each other.

When a drive voltage is applied to the drive electrode 41, an electric field is generated between the drive electrode 41 and the detection electrode 42. When an object approaches the proximity sensor 4 with the electric field generated, the electric field generated between the drive electrode 41 and the detection electrode 42 changes. A change of capacitance due to the change of the electric field is detected by the detection electrode 42, and thereby, whether or not the object approaches may be detected.

Note that the detection system of the proximity sensor 4 according to the embodiment is a mutual capacitance system, however, may be a self-capacitance system. The mutual capacitance proximity sensor 4 may have higher object detection accuracy than the self-capacitance sensor.

Here, the proximity sensor 4B and the proximity sensor 4C are placed side by side on the outer surface 1220 of the second arm 12 shown in FIG. 6 as described above. Each of these sensors has the above described drive electrode 41 and detection electrode 42. The drive electrode 41 of the proximity sensor 4B is separated and electrically insulated from the drive electrode 41 of the proximity sensor 4C. Similarly, the detection electrode 42 of the proximity sensor 4B is separated and electrically insulated from the detection electrode 42 of the proximity sensor 4C.

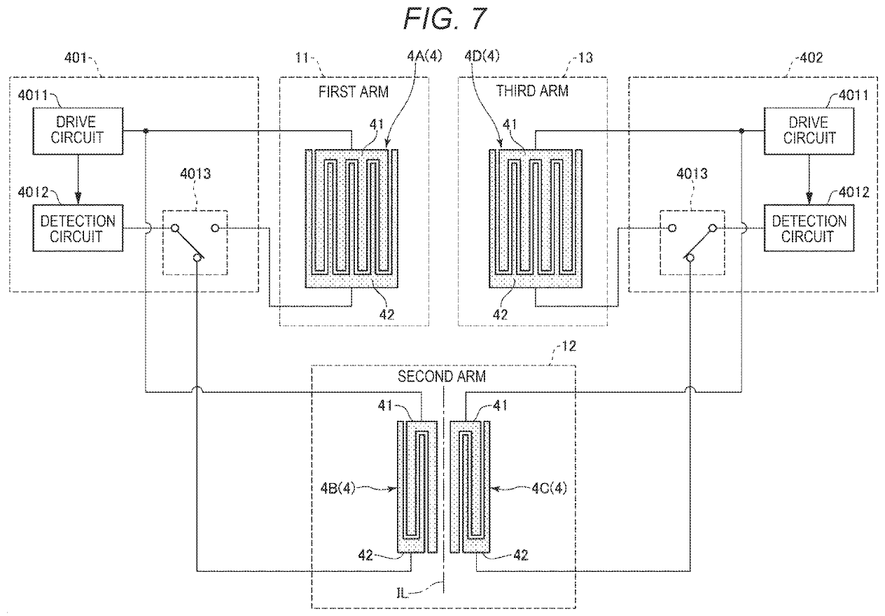

FIG. 7 is the block diagram showing the proximity sensor 4 in FIG. 6 and the first sensor circuit 401 and the second sensor circuit 402 in FIG. 2.

The second arm 12 shown in FIG. 6 has the elongated shape as described above. When the second arm 12 is in the posture shown in FIG. 6, of the outer surface 1220 of the second arm 12, an area 121 forms a nearly rectangular shape having two long sides 121b along the Z-axis and two short sides 121a along the second pivot axis O2 parallel to the Y-axis.

Here, midpoints of the respective short sides 121a are referred to as “M1”. Note that, when the lengths of the two short sides 121a are different from each other, midpoints of the two short sides in a rectangle having the maximum area that can be drawn in the area 121 may be set as M1.

A line connecting the midpoints M1 is referred to as “imaginary line IL”. The imaginary line IL is a line orthogonal to the second pivot axis O2. Further, Of the area 121, a portion at the first arm 11 side of the imaginary line IL is referred to as “first arm-side portion 1211” and a portion at the third arm 13 side of the imaginary line IL is referred to as “third arm-side portion 1212”. That is, the area 121 shown in FIG. 6 is divided into two portions at the Y-axis plus side and the Y-axis minus side at the boundary on the imaginary line IL parallel to the Z-axis. The proximity sensor 4B is placed in the first arm-side portion 1211 and the proximity sensor 4C is placed in the third arm-side portion 1212.

Further, as shown in FIG. 2, the proximity sensors 4A, 4B are respectively electrically coupled to the first sensor circuit 401. On the other hand, the proximity sensors 4C, 4D are respectively electrically coupled to the second sensor circuit 402. In addition, the first sensor circuit 401 and the second sensor circuit 402 are respectively electrically coupled to the control apparatus 8.

As will be described later, the first sensor circuit 401 is housed inside of the first arm 11. The first sensor circuit 401 includes a drive circuit 4011 that applies the drive voltages to the drive electrodes 41 of the proximity sensors 4A, 4B and a detection circuit 4012 that detects amounts of electric charge output from the detection electrodes 42 in synchronization with the drive voltages. As will be described later, the second sensor circuit 402 is housed inside of the third arm 13. The circuit includes a drive circuit 4011 that applies the drive voltages to the drive electrodes 41 of the proximity sensors 4C, 4D and a detection circuit 4012 that detects amounts of electric charge output from the detection electrodes 42 in synchronization with the drive voltages.

Further, the first sensor circuit 401 shown in FIG. includes a switching element 4013 that switches the coupling destination of the detection circuit 4012 between the detection electrode 42 of the proximity sensor 4A and the detection electrode 42 of the proximity sensor 4B. The second sensor circuit 402 shown in FIG. 7 includes a switching element 4013 that switches the coupling destination of the detection circuit 4012 between the detection electrode 42 of the proximity sensor 4C and the detection electrode 42 of the proximity sensor 4D. The respective switching elements 4013 are switched at predetermined time intervals and enable one of the proximity sensors 4A, 4B and one of the proximity sensors 4C, 4D at the predetermined time intervals.

The detection results by the detection circuits 4012 are output to the sensor control unit 82 of the control apparatus 8 as shown in FIG. 2. In the sensor control unit 82, an object located around the robot arm 10 is detected based on the detection results by the detection circuits 4012, specifically, the changes of the amounts of electric charge or the like. In the drive control unit 81, the actuation of the robot arm 10 is stopped or decelerated based on the object detection result in the sensor control unit 82.

Here, problems of related art are explained.

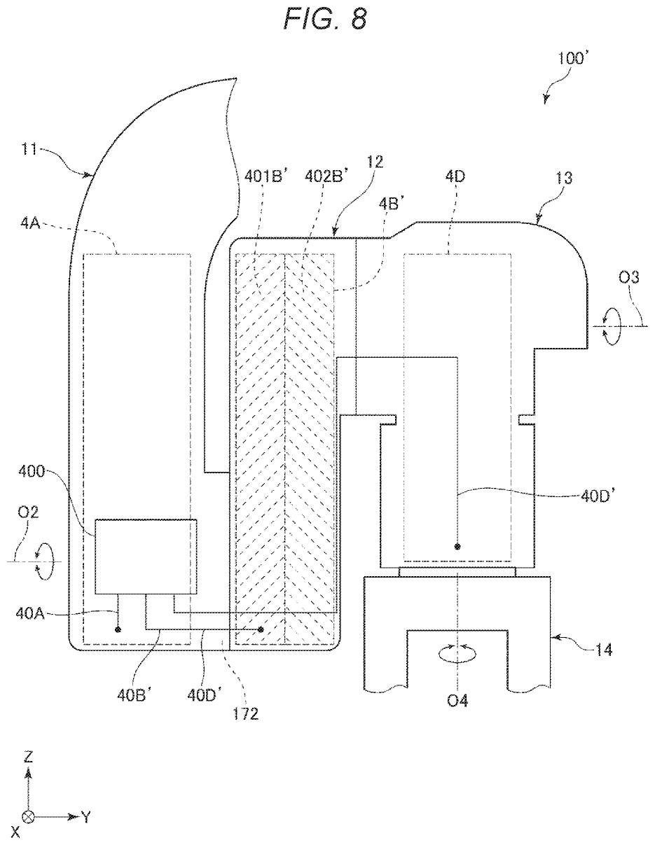

FIG. 8 shows the placement example of the proximity sensor, the placement example of the sensor circuit, and the wiring example in the robot of related art. Note that, in FIG. 8, for convenience of explanation, the same elements as the above described elements have the same signs.

In a robot 100′ of related art, one proximity sensor 4B′ is placed on the second arm 12. Further, in the robot 100′, one sensor circuit 400 is housed inside of the first arm 11. The detectable range of the proximity sensor 4B′ as a capacitance sensor spreads in a range at a predetermined distance from the surface of the proximity sensor 4B′. Accordingly, for example, when the second arm 12 pivots about the second pivot axis O2 relative to the first arm 11, the first arm 11 enters the detectable range of the proximity sensor 4B′ depending on the pivot angle. Then, the amount of electric charge output from the detection electrode 42 of the proximity sensor 4B′ increases with the amount of entry of the first arm 11. As a result, from the sensor circuit 400, a detection result at the equal level to that when some object enters the detectable range of the proximity sensor 4B′ is unintentionally output. Accordingly, in a sensor control unit (not shown), approach of an object is determined and the actuation of the robot arm 10 is stopped or decelerated from necessity.

On the other hand, to avoid the restriction of the actuation of the robot 100′, “threshold” for determination of approach of an object in the sensor control unit may be reduced. That is, the sensitivity of the proximity sensor 4B′ may be reduced.

However, when the first arm 11 enters the detectable range of the proximity sensor 4B′, the capacitance changes with the entry of the first arm 11 only in a portion 401B′ of the proximity sensor 4B′ at the first arm 11 side. Therefore, of the proximity sensor 4B′, a portion 402B′ at the third arm 13 side is hardly affected by the entry of the first arm 11. However, when the sensitivity is reduced as described above, the sensitivity is lower in the entire proximity sensor 4B′. Accordingly, the portion 402B′ of the proximity sensor 4B′ is also affected by the sensitivity reduction.

Similarly, when the third arm 13 enters the detectable range of the proximity sensor 4B′, the capacitance changes with the entry of the third arm 13 only in the portion 402B′ of the proximity sensor 4B′ at the third arm 13 side. Therefore, of the proximity sensor 4B′, the portion 401B′ at the first arm 11 side is hardly affected by the entry of the third arm 13. However, when the sensitivity is reduced as described above, the sensitivity is lower in the entire proximity sensor 4B′. Accordingly, the portion 401B′ of the proximity sensor 4B′ is also affected by the sensitivity reduction.

On the other hand, in the embodiment, the proximity sensors 4B, 4C coupled to the different sensor circuits are provided side by side on the outer surface of the second arm 12. Specifically, as shown in FIG. 6, when the area 121 on the outer surface of the second arm 12 is divided into two portions, the proximity sensor 4B is placed in the first arm-side portion 1211 at the first arm 11 side and the proximity sensor 4C is placed in the third arm-side portion 1212 at the third arm 13 side. Further, the proximity sensor 4A placed on the first arm 11 and the proximity sensor 4B placed in the first arm-side portion 1211 are respectively coupled to the first sensor circuit 401 as shown in FIGS. 2 and 7. The proximity sensor 4D placed on the third arm 13 and the proximity sensor 4C placed in the third arm-side portion 1212 are respectively coupled to the second sensor circuit 402 as shown in FIGS. 2 and 7. Accordingly, in consideration of the position relationship between the first arm 11 and the proximity sensors 4B, 4C, a distance L1 from the first arm 11 to the proximity sensor 4B (first proximity sensor) along the second pivot axis O2 is shorter than a distance L2 from the first arm 11 to the proximity sensor 4C (second proximity sensor) along the second pivot axis O2 as shown in FIG. 6. That is, the distance L1 and the distance L2 are different from each other. The magnitude relationship between the distances L1, L2 according to the embodiment is substantially maintained regardless of the pivot angle of the second arm 12 relative to the first arm 11.

Note that the distance L1 refers to the minimum value of the separation distance between the first arm 11 and the proximity sensor 4B in the entire pivot range when the second arm 12 is pivoted relative to the first arm 11. Similarly, the distance L2 refers to the minimum value of the separation distance between the first arm 11 and the proximity sensor 4C in the entire pivot range when the second arm 12 is pivoted relative to the first arm 11.

As described above, in the area 121, the proximity sensors 4B, 4C coupled to the different sensor circuits are provided side by side and the placement thereof is optimized, and thereby, the adverse effect when the first arm 11 or the third arm 13 interferes with the detectable ranges of the proximity sensors 4B, 4C may be minimized.

Specifically, the area 121 is divided into the two portions at the first arm 11 side and the third arm 13 side, and the proximity sensors 4B, 4C independent from each other are provided side by side. Accordingly, for example, even when the sensitivity of the first sensor circuit 401 coupled to the proximity sensor 4B is temporarily reduced in consideration of the entry of the first arm 11 into the detectable range of the proximity sensor 4B, it is not necessary to reduce the sensitivity of the second sensor circuit 402 coupled to the proximity sensor 4C. Accordingly, in the detectable range of the proximity sensor 4C, the original good sensitivity may be maintained and approach of an object may be detected more accurately. Similarly, even when the sensitivity of the second sensor circuit 402 coupled to the proximity sensor 4C is temporarily reduced in consideration of the entry of the third arm 13 into the detectable range of the proximity sensor 4C, it is not necessary to reduce the sensitivity of the first sensor circuit 401 coupled to the proximity sensor 4B. Accordingly, in the detectable range of the proximity sensor 4B, the original good sensitivity may be maintained and approach of an object may be detected more accurately.

The second arm 12 with the proximity sensor 4B placed thereon pivots about the second pivot axis O2 relative to the first arm 11 with the proximity sensor 4A placed thereon. Accordingly, a position relationship in which an electric field generated in the drive electrode 41 of the proximity sensor 4A acts on the detection electrode 42 of the proximity sensor 4B is produced depending on the pivot angle.

In the viewpoint, in the embodiment, as shown in FIG. 7, the proximity sensor 4A placed on the first arm 11 is coupled to the first sensor circuit 401 with the proximity sensor 4B. Accordingly, in the proximity sensors 4A, 4B, the drive voltages changing at the same time with each other may be applied and the amounts of electric charge may be detected at the same time with each other. Thereby, even when the capacitance of the proximity sensors 4A, 4B is subjected to interference and the amounts of electric charge output from the detection electrodes 42 increase or decrease due to the pivot of the second arm 12 relative to the first arm 11, the increase or decrease of the amounts of electric charge may be easily corrected. This is because the time when the drive voltage changes and the time when the amount of electric charge is detected are synchronized and a constant correlation may be provided between the amount of increase or decrease in the amount of electric charge due to interference and the posture of the second arm 12 relative to the first arm 11. That is, randomness is suppressed in the increase or decrease of the amount of electric charge with interference and reproducibility is produced, and thereby, the increase or decrease of the amount of electric charge with interference may be easily calculated and the increase or decrease of the amount of electric charge with approach of an object to the proximity sensors 4A, 4B that should be originally obtained may be obtained more accurately.

Similarly, in the embodiment as shown in FIG. 7, the proximity sensor 4D placed on the third arm 13 is coupled to the second sensor circuit 402 with the proximity sensor 4C. Accordingly, in the proximity sensors 4C, 4D, the drive voltages changing at the same time with each other may be applied and the amounts of electric charge may be detected at the same time with each other. Thereby, even when the capacitance of the proximity sensors 4C, 4D is subjected to interference and the amounts of electric charge output from the detection electrodes 42 increase or decrease due to the pivot of the third arm 13 relative to the second arm 12, the increase or decrease of the amounts of electric charge may be easily corrected. This is because the time when the drive voltage changes and the time when the amount of electric charge is detected are synchronized and a constant correlation may be provided between the amount of increase or decrease in the amount of electric charge due to interference and the posture of the third arm 13 relative to the second arm 12. That is, randomness is suppressed in the increase or decrease of the amount of electric charge with interference and reproducibility is produced, and thereby, the increase or decrease of the amount of electric charge with interference may be easily calculated and the increase or decrease of the amount of electric charge with approach of an object to the proximity sensors 4C, 4D that should be originally obtained may be obtained more accurately.

In the robot 100′ of related art shown in FIG. 8, the proximity sensor 4A is placed on the first arm 11, the above described proximity sensor 4B′ is placed on the second arm 12, and the proximity sensor 4D is placed on the third arm 13. The respective detection electrodes 42 of these three proximity sensors 4A, 4B′, 4D are electrically coupled to the one sensor circuit 400 housed inside of the first arm 11 via wires 40A, 40B′, 40D′ housed inside of the robot arm 10. Accordingly, the extension of the wire 40D′ is longer because the sensor circuit 400 and the proximity sensor 4D are particularly physically separated. Therefore, an analog signal transmitted through the wire 40D′, specifically, the change of the amount of electric charge output from the detection electrode 42 is easily affected by disturbance noise and parasitic capacitance increases. As a result, there is a problem that the object detection accuracy obtained from the amount of increase or decrease of the amount of electric charge is lower. Further, it is necessary to pass the plurality of wires 40B′, 40D′ through the joint 172 between the first arm 11 and the second arm 12. Thus, there is a problem that the degree of freedom of design within the joint 172 is lower.

On the other hand, in the embodiment, the above described problems are solved by division of the one sensor circuit 400 into two.

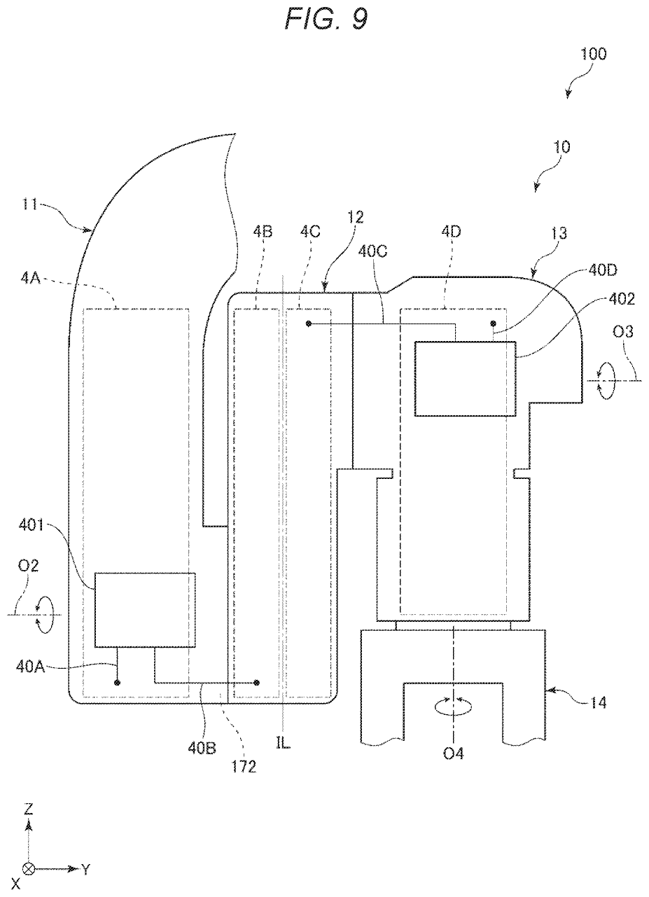

FIG. 9 is the front view showing the placement of the proximity sensor 4 in FIG. 6 and the placement of the first sensor circuit 401 and the second sensor circuit 402 in FIG. 2.

The robot 100 shown in FIG. 9 includes the first sensor circuit 401 housed inside of the first arm 11 and the second sensor circuit 402 housed inside of the third arm 13. The respective detection electrodes 42 of the proximity sensors 4A, 4B are electrically coupled to the first sensor circuit 401 via the wires 40A, 40B housed inside of the robot arm 10, the respective detection electrodes 42 of the proximity sensors 4C, 4D are electrically coupled to the second sensor circuit 402 via the wires 40C, 40D housed inside of the robot arm 10. Accordingly, in FIG. 9, the extensions of the respective wires 40A, 40B, 40C, 40D may be made shorter than the extensions of the respective wires 40A, 40B′, 40D′ shown in FIG. 8. As a result, analog signals transmitted through the respective wires 40A, 40B, 40C, 40D are hardly affected by disturbance noise. Thereby, in the robot 100 according to the embodiment, approach of an object may be detected more accurately. Further, in FIG. 9, the number of wires passed through the joint 172 may be reduced compared to that in FIG. 8. Thereby, the degree of freedom of design within the joint 172 may be improved.

The placement of the first sensor circuit 401 and the second sensor circuit 402 is not limited to that described above, but appropriately changed so that the extensions of the respective wires 40A, 40B, 40C, 40D may be as short as possible. Further, the robot 100 may include three or more sensor circuits.

Note that, though not illustrated, in the second arm 12 shown in FIG. 6, another area crossing the X-axis, i.e., an area located at the opposite side to the area 121 may be divided into two portions at a boundary of an imaginary line (not shown) like the area 121. Further, the same sensor as the proximity sensor 4B may be provided in the portion at the first arm 11 side of the imaginary line and the same sensor as the proximity sensor 4C may be provided in the portion at the third arm 13 side.

Further, though not illustrated, in the second arm 12 shown in FIG. 6, when each of two areas corresponding to the two short sides 121a of the area 121, i.e., two areas crossing the Z-axis is divided into two portions at a boundary of an imaginary line (not shown) like the area 121, the same sensor as the proximity sensor 4B may be provided in the portion at the first arm 11 side of the imaginary line and the same sensor as the proximity sensor 4C may be provided in the portion at the third arm 13 side.

Furthermore, though not illustrated, in the second arm 12 shown in FIG. 6, the same sensor as the proximity sensor 4B may be provided in the area located at the first arm 11 side of two areas corresponding to the two long sides 121b of the area 121. Similarly, the same sensor as the proximity sensor 4C may be provided in the area located at the third arm 13 side.

The above described sensors are provided, and thereby, the sensor provided in the portion at the first arm 11 side is coupled to the first sensor circuit 401 and the extension of the wire may be shortened. Accordingly, the effect on the detection signal by disturbance noise may be suppressed and lowering of the degree of freedom of design within the joint may be avoided. Similarly, the sensor provided in the portion at the third arm 13 side is coupled to the second sensor circuit 402 and the extension of the wire may be shortened. Accordingly, the effect on the detection signal by disturbance noise may be suppressed and lowering of the degree of freedom of design within the joint may be avoided.

Note that, in the area 121, the proximity sensor 4B and the proximity sensor 4C are provided side by side with the imaginary line IL in between, however, in this case, electric lines of force (not shown) extending from the respective drive electrodes 41 run out in a direction orthogonal to the area 121, and then, reach the adjacent detection electrodes 42. Accordingly, for example, it is considered that there are very few electric lines of force reaching the detection electrode 42 of the proximity sensor 4C from the drive electrode 41 of the proximity sensor 4B. In the viewpoint, even when the proximity sensors 4B, 4C are provided in the different circuits side by side in the area 121, the effects on each other are restricted.

On the other hand, the placement shown in FIG. 9 is employed, and thereby, the above described advantages, i.e., the suppression of the effect by disturbance noise and the improvement of the degree of freedom of design of the joint may be enjoyed and the proximity sensors 4B, 4C may be provided in sufficient density in the area 121. Accordingly, the space beyond the detectable range of the proximity sensor 4 may be minimized and the robot 100 with less “blind spots” for the proximity sensor 4 may be realized.

As described above, the robot 100 according to the embodiment includes the first arm 11, the second arm 12 to be displaced relative to the first arm 11, the capacitance proximity sensor 4B (first proximity sensor) provided on the second arm 12, and the capacitance proximity sensor 4C (second proximity sensor) provided on the second arm 12. Further, as described above, the distance L1 from the first arm 11 to the proximity sensor 4B is different from the distance L2 from the first arm 11 to the proximity sensor 4C.

According to the robot 100, the proximity sensors 4B, 4C coupled to the sensor circuits different from each other are provided side by side on the second arm 12, and thereby, in view of the interference between the proximity sensor 4B and the first arm 11, it is not necessary to reduce the sensitivity of the proximity sensor 4C. Therefore, according to the embodiment, the robot 100 for which sensitivity is easily increased may be realized.

Note that, when the proximity sensor 4B (first proximity sensor) and the proximity sensor 4C (second proximity sensor) are provided side by side on the second arm 12 as described above, the sensitivity of the proximity sensor 4B and the sensitivity of the proximity sensor 4C may be made different. Specifically, in the sensor control unit 82, the detection result output from the first sensor circuit 401 and the detection result output from the second sensor circuit 402 are respectively compared to “threshold” and, when the detection result is equal to or larger than the threshold, approach of an object to the robot arm 10 may be determined. In this case, the threshold applied to the detection result output from the first sensor circuit 401 and the threshold applied to the detection result output from the second sensor circuit 402 may be made different from each other. The degree of the interference of the first arm 11 with the proximity sensor 4B and the degree of the interference of the third arm 13 with the proximity sensor 4C are often different depending on the design of the robot arm 10, and thus, the sensitivity may be optimized in the proximity sensors 4B, 4C using the different thresholds.

As described above, the second arm 12 pivots about the second pivot axis O2 as the pivot axis relative to the first arm 11. When the line passing through the midpoint of the length of the second arm 12 along the second pivot axis O2, i.e., the above described midpoints M1 of the short sides 121a and being orthogonal to the second pivot axis O2 is the imaginary line IL, the distance L1 from the first arm 11 to the proximity sensor 4B (first proximity sensor) is shorter than a distance L3 from the first arm 11 to the imaginary line IL as shown in FIG. 6. Further, the distance L2 from the first arm 11 to the proximity sensor 4C (second proximity sensor) is longer than the distance L3 from the first arm 11 to the imaginary line IL.

The proximity sensor 4B and the proximity sensor 4C are placed at the boundary on the imaginary line IL, and thereby, the detectable range of the proximity sensor 4 around the second arm 12 may be divided into two between the proximity sensor 4B and the proximity sensor 4C. Accordingly, a situation where the sensitivity is significantly different between the proximity sensor 4B and the proximity sensor 4C is harder to be created and, the robot 100 including the proximity sensor 4 with uniform higher sensitivity as a whole may be realized.

The proximity sensor 4B (first proximity sensor) shown in FIG. 6 is the mutual capacitance sensor including the drive electrode 41 (first drive electrode) and the detection electrode 42 (first detection electrode). The mutual capacitance proximity sensor 4B may provide higher object detection accuracy than the self-capacitance proximity sensor. Accordingly, the robot 100 with higher reliability may be realized.

The proximity sensor 4C (second proximity sensor) shown in FIG. 6 is the mutual capacitance sensor including the drive electrode 41 (second drive electrode) and the detection electrode 42 (second detection electrode) like the proximity sensor 4B. The mutual capacitance proximity sensor 4C may provide higher object detection accuracy than the self-capacitance proximity sensor. Accordingly, the robot 100 with higher reliability may be realized.

The detection methods of the proximity sensors 4B, 4C respectively shown in FIG. 6 use the mutual capacitance system with the drive electrodes 41 and the detection electrodes 42 as described above. The sensors are configured so that the detection electrode 42 (first detection electrode) of the proximity sensor 4B and the detection electrode 42 (second detection electrode) of the proximity sensor 4C may not be placed between the drive electrode 41 (first drive electrode) of the proximity sensor 4B and the drive electrode 41 (second drive electrode) of the proximity sensor 4C. That is, the drive electrode 41 of the proximity sensor 4B and the drive electrode 41 of the proximity sensor 4C are placed next to each other.

Around the drive electrode 41, the drive electrode 41 functions as a shield. Accordingly, even when the drive electrode 41 of the proximity sensor 4B and the drive electrode 41 of the proximity sensor 4C are placed next to each other, the possibility that the electrodes adversely affect each other is lower. On the other hand, for example, when the detection electrode 42 of the proximity sensor 4B and the drive electrode 41 of the proximity sensor 4C are placed next to each other, the change of the amount of electric charge output from the detection electrode 42 is susceptible to the drive signal applied to the drive electrode 41 of the proximity sensor 4C.

On the other hand, the above described placement is employed, and thereby, the drive electrode 41 intervenes between the detection electrodes 42. Accordingly, noise is harder to be superimposed on the detection signal and an object may be detected more accurately in the proximity sensor 4.

### 2. First Modified Example

Next, the first modified example of the robot 100 according to the above described embodiment will be explained.

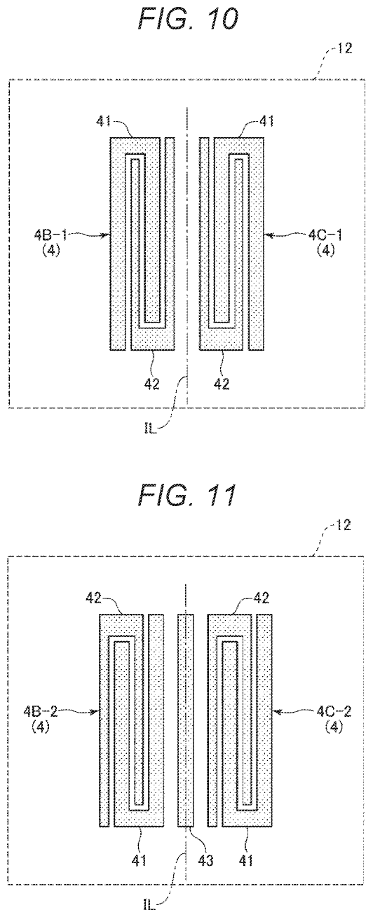

FIG. 10 is the partially enlarged view showing proximity sensors 4B-1, 4C-1 placed on the second arm 12 of the robot 100 according to the first modified example.

As below, the first modified example will be explained. In the following description, the explanation will be made with a focus on differences from the above described embodiment and the explanation of the same items will be omitted. Note that, in FIG. 10, the same configurations as those of the above described embodiment have the same signs.

The detection methods of the proximity sensors 4B-1, 4C-1 shown in FIG. 10 respectively use the mutual capacitance system with the drive electrodes 41 and the detection electrodes 42 as described above. The sensors are configured so that the drive electrode 41 (first drive electrode) of the proximity sensor 4B-1 and the drive electrode 41 (second drive electrode) of the proximity sensor 4C-1 may not be placed between the detection electrode 42 (first detection electrode) of the proximity sensor 4B-1 and the detection electrode 42 (second detection electrode) of the proximity sensor 4C-1. That is, the detection electrode 42 of the proximity sensor 4B-1 and the detection electrode 42 of the proximity sensor 4C-1 are placed next to each other.

The above described placement is employed, and thereby, compared to a case where the detection electrode 42 of the proximity sensor 4B-1 and the drive electrode 41 of the proximity sensor 4C-1 are placed next to each other, noise is harder to be superimposed on the detection signal though not to the extent of the above described embodiment. Accordingly, compared to a case where the drive electrode 41 and the detection electrode 42 in the different circuits are placed next to each other, object detection accuracy in the proximity sensors 4B-1, 4C-1 may be increased.

In the above described first modified example, the same advantages as those of the above described embodiment may be obtained.

### 3. Second Modified Example

Next, the second modified example of the robot 100 according to the above described embodiment will be explained.

FIG. 11 is the partially enlarged view showing proximity sensors 4B-2, 4C-2 placed on the second arm 12 of the robot 100 according to the second modified example.

As below, the second modified example will be explained. In the following description, the explanation will be made with a focus on differences from the above described embodiment and the explanation of the same items will be omitted. Note that, in FIG. 11, the same configurations as those of the above described embodiment have the same signs.

The detection methods of the proximity sensors 4B-2, 4C-2 shown in FIG. 11 respectively use the mutual capacitance system with the drive electrodes 41 and the detection electrodes 42 as described above. The robot 100 according to the second modified example has a ground electrode 43 provided between the proximity sensor 4B-2 and the proximity sensor 4C-2 and having a ground potential.

Thereby, for example, as shown in FIG. 11, even when the drive electrode 41 of the proximity sensor 4B-2 and the detection electrode 42 of the proximity sensor 4C-2 are placed next to each other, the ground electrode 43 is provided between the electrodes, and thereby, the change of the amount of electric charge output from the detection electrode 42 may be harder to be affected by the drive signal applied to the drive electrode 41 of the proximity sensor 4B-2. That is, the ground electrode 43 functions as a shield and noise is harder to be superimposed on the change of the amount of electric charge output from the detection electrode 42. As a result, object detection accuracy in the proximity sensors 4B-2, 4C-2 may be further increased.

In the above described second modified example, the same advantages as those of the above described embodiment may be obtained.

As above, the robot according to the present disclosure is explained based on the illustrated preferred embodiments, however, the present disclosure is not limited to those. The configurations of the respective parts may be replaced by arbitrary configurations having the same functions. Or, another arbitrary configuration may be added to the present disclosure.

Further, the robot according to the present disclosure is not limited to the suspended vertical articulated robot as long as the robot has the robot arm. The robot may be another robot such as e.g. another type of vertical articulated robot, dual-arm robot, or scalar robot. The number of arms of the robot arm is not limited to the number of the above described embodiment, but may be from one to five, seven, or more.

What is claimed is:

1. A robot comprising:
a first arm;
a second arm to be displaced relative to the first arm;
a capacitance-type first proximity sensor provided on the second arm; and
a capacitance-type second proximity sensor provided on the second arm, wherein
a distance from the first arm to the first proximity sensor is different from a distance from the first arm to the second proximity sensor.

2. The robot according to claim 1, wherein
sensitivity of the first proximity sensor is different from sensitivity of the second proximity sensor.

3. The robot according to claim 1, wherein
the second arm pivots about a pivot axis relative to the first arm, and
when a line passing through a midpoint of a length of the second arm along the pivot axis and being orthogonal to the pivot axis is an imaginary line, the distance from the first arm to the first proximity sensor is shorter than a distance from the first arm to the imaginary line and the distance from the first arm to the second proximity sensor is longer than the distance from the first arm to the imaginary line.

4. The robot according to claim 1, wherein
a detection system of the first proximity sensor is a mutual capacitance system with a first drive electrode and a first detection electrode.

5. The robot according to claim 1, wherein
a detection system of the second proximity sensor is a mutual capacitance system with a second drive electrode and a second detection electrode.

6. The robot according to claim 1, wherein
the first proximity sensor is of a mutual capacitance system with a first drive electrode and a first detection electrode,
the second proximity sensor is of a mutual capacitance system with a second drive electrode and a second detection electrode, and
the first detection electrode and the second detection electrode are not placed between the first drive electrode and the second drive electrode.

7. The robot according to claim 1, wherein
the first proximity sensor is of a mutual capacitance system with a first drive electrode and a first detection electrode,
the second proximity sensor is of a mutual capacitance system with a second drive electrode and a second detection electrode, and
the first drive electrode and the second drive electrode are not placed between the first detection electrode and the second detection electrode.

8. The robot according to claim 1, further comprising a ground electrode provided between the first proximity sensor and the second proximity sensor and having a ground potential.
